(19) United States
(12) Patent Application Publication
(10) Pub. No.: US 2025/0014956 A1
(43) Pub. Date: Jan. 9, 2025

(54) ELECTRONIC DEVICE AND METHOD OF MANUFACTURING THE SAME

(71) Applicant: InnoLux Corporation, Miao-Li County (TW)

(72) Inventors: Ker-Yih KAO, Miao-Li County (TW); Ju-Li WANG, Miao-Li County (TW); Zi-Zhong WANG, Miao-Li County (TW); Yen-Fu LIU, Miao-Li County (TW)

(21) Appl. No.: 18/741,160

(22) Filed: Jun. 12, 2024

Related U.S. Application Data
(60) Provisional application No. 63/512,314, filed on Jul. 7, 2023.

(30) Foreign Application Priority Data
Mar. 26, 2024 (CN) 202410348920.6

(51) Int. Cl. H01L 23/31; H01L 23/00; H01L 23/367; H01L 23/58

(52) U.S. Cl. CPC H01L 23/3107; H01L 23/367; H01L 23/58; H01L 24/25; H01L 2224/25171

(57) ABSTRACT

An electronic device includes an electronic unit having a first side and a second side; an encapsulation layer surrounding the electronic unit and having a plurality of openings exposing the second side of the electronic unit; a first circuit structure disposed on the first side of the electronic unit and electrically connected to the electronic unit; a second circuit structure disposed on the second side of the electronic unit; a via penetrating the encapsulation layer and electrically connecting the first circuit structure to the second circuit structure; and a heat dissipation layer disposed on the second side of the electronic unit, wherein the heat dissipation layer contacts the electronic unit through the plurality of openings.

### CROSS REFERENCE TO RELATED APPLICATIONS

This application claims priority of China Patent Application No. 202410348920.6, filed on Mar. 26, 2024, which claims the benefit of U.S. Provisional Application No. 63/512,314, filed Jul. 7, 2023, the entirety of which is incorporated by reference herein.

### BACKGROUND OF THE INVENTION

### Field of the Invention

The present disclosure relates to an electronic device and a method of manufacturing the same, and in particular, to an electronic device comprising a heat dissipation layer and a method of manufacturing the same.

### Description of the Related Art

With the development of digital technology, electronic devices are being widely used in all aspects of daily life. An electronic device may include power elements, packaging elements, or other electronic elements. A conventional packaging element has a large size and thickness due to wire bonding. Therefore, when a conventional packaging element is electrically connected to other electronic elements, the reliability and electrical properties of the electronic device may be degraded due to the long electrical path.

### BRIEF SUMMARY OF THE INVENTION

An embodiment of the present disclosure provides an electronic device. The electronic device includes an electronic unit having a first side and a second side, wherein the first side is opposite the second side; an encapsulation layer surrounding the electronic unit and having a plurality of openings exposing the second side of the electronic unit; a first circuit structure disposed on the first side of the electronic unit and electrically connected to the electronic unit; a second circuit structure disposed on the second side of the electronic unit; a via penetrating the encapsulation layer and electrically connecting the first circuit structure to the second circuit structure; and a heat dissipation layer disposed on the second side of the electronic unit, wherein the heat dissipation layer contacts the electronic unit through the plurality of openings.

An embodiment of the present disclosure provides a method of manufacturing an electronic device. The method of manufacturing an electronic device includes providing an electronic unit, a via, and an encapsulation layer. The encapsulation layer surrounds the electronic unit and the via and exposes the first side of the electronic unit and the top portion of the conductive element of the via. The method includes providing a first circuit structure on the first side of the electronic unit and the via. The method includes forming a plurality of openings to expose a portion of the second side of the electronic unit. The method includes forming a heat dissipation layer on the second side of the electronic unit and forming a second circuit structure on the via. The second circuit structure is electrically connected to the first circuit structure through the via, and the heat dissipation layer is disposed between the second circuit structure and the second side of the electronic unit.

### BRIEF DESCRIPTION OF THE DRAWINGS

The present invention can be more fully understood by reading the subsequent detailed description and examples with references made to the accompanying drawings, wherein:

FIG. 1A is a plan view of an electronic device according to an embodiment of the present disclosure;

FIG. 1B is a cross-sectional schematic view of the electronic device shown in FIG. 1A taken along a line AA′ according to an embodiment of the present disclosure;

FIG. 1C is a cross-sectional schematic view of the electronic device shown in FIG. 1A taken along a line AA′ according to another embodiment of the present disclosure;

FIG. 2 is a flowchart of a method of manufacturing an electronic device according to an embodiment of the present disclosure;

FIGS. 3A to 3D are schematic views of semi-finished products of an electronic device during manufacture of the electronic device according to an embodiment of the present disclosure;

FIGS. 4A to 4C are schematic views of semi-finished products of an electronic device during manufacture of the electronic device according to an embodiment of the present disclosure;

FIGS. 5A to 5C are schematic views of semi-finished products of an electronic device during manufacture of the electronic device according to an embodiment of the present disclosure;

FIGS. 6A to 6E are schematic views of semi-finished products of an electronic device during manufacture of the electronic device according to an embodiment of the present disclosure; and

FIGS. 7A to 7F are schematic views of semi-finished products of an electronic device during the manufacture of the electronic device according to an embodiment of the present disclosure.

### DETAILED DESCRIPTION OF THE INVENTION

The following description is made for the purpose of illustrating the general principles of the disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

The present disclosure may be understood by reference to the following detailed description in conjunction with the accompanying drawings. It should be noted that in order to facilitate understanding by the reader and to simplify the drawings, only a portion of the electronic device is shown in the drawings of the present disclosure and specific elements in the drawings are not shown to actual scale. In addition, the number and size of the elements in the drawings are for illustrative purposes only and are not intended to limit the scope of this disclosure.

Directional terms mentioned in the disclosure, such as “up”, “down”, “front”, “back”, “left”, “right” only refer to directions of the accompanying drawings. Therefore, the directional terms used herein are illustrative and not intended to limit the disclosure. It should be understood that if a device in an accompanying drawing is turned upside down, elements recited on the “bottom” side will become the elements on the “top” side. In the accompanying drawings, the drawings illustrate general features of the methods, structures and/or materials used in specific embodiments. However, these accompanying drawings should not be construed as defining or limiting the scope or property of what is covered by these embodiments. For example, relative sizes, thicknesses and positions of the various layers, regions and/or structures may be reduced or enlarged for clarity.

In the present disclosure, descriptions of a structure (or layer, element or substrate) being on/above another structure (or layer, element or substrate) may mean that the two structures are adjacent and directly connected, or that the two structures are adjacent and indirectly connected. Indirect connection means that there is at least one intermediate structure (or intermediate layer, intermediate element, intermediate substrate, intermediate spacer) between two structures. A lower surface of the structure is adjacent to or directly connected to an upper surface of the intermediate structure, and an upper surface of the other structure is adjacent to or directly connected to a lower surface of the intermediate structure. The intermediate structure may be a single-layer or multi-layer physical structure or a non-physical structure without limitation. In the disclosure, when a structure is disposed “on” another structure, it may mean that the structure is “directly” on the other structure, or that the structure is “indirectly” on the other structure, i.e. there is at least one structure between the one structure and the other structure.

The phrase “A surrounding B” used herein means that at least a portion of B is within A, and in the cross-sectional view, A is in direct or indirect contact with at least one side surface of B. The phrase “A directly contacts B” used herein means that there is no intermediary structure between A and B.

In some embodiments of the present disclosure, unless otherwise defined, terms related to joining and connecting, such as “connection”, “interconnection”, etc., may mean that two structures are in direct contact, or may also mean that the two structures are not in direct contact (indirectly contact) and other structures are between the two structures. The terms related to joining and connecting may also include the situation where both structures are movable or both structures are fixed. In addition, the term “electrical connection” includes the transfer of energy between two structures by means of a direct or indirect electrical connection, or the transfer of energy between two separate structures by means of mutual induction.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. The term “a-b” refers to a range that includes all values greater than or equal to a, less than or equal to b, and all values between a and b.

Ordinal numbers used in the specification and claims, such as “first”, “second”, etc., are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second element in the claim.

Throughout the disclosure and the appended claims, some terms are used to refer to specific elements. Those skilled in the art will understand that electronic device manufacturers may refer to the same element by different names. The disclosure is not intended to differentiate between elements that have the same function but have different names.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

The electronic device may include a power module, an imaging device, a semiconductor device, a display device, a light emitting device, a backlight device, an antenna device, a sensing device, a packaging device, a splicing device, a touch electronic device (touch display), a curved electronic device (curved display) or a non-rectangular electronic device (free shape display), but is not limited thereto. The electronic device may include, for example, liquid crystals, light emitting diodes, fluorescences, phosphors, other suitable display medias, or any combination of the foregoing, but are not limited thereto. The display device may be a non-self-luminous display device or a self-luminous display device. The antenna device may be a liquid crystal type antenna device or a non-liquid crystal type antenna device. The sensing device may be a sensing device that senses capacitance, light, heat energy or ultrasonic waves, but is not limited thereto. The splicing device may be, for example, a display splicing device or an antenna splicing device, but is not limited thereto.

The electronic device may be a bendable or flexible electronic device. The shape of the electronic device may be a rectangular shape, a circular shape, a polygonal shape, a shape with curved edges, or other suitable shapes. The processes for electronic devices described in the present disclosure may be applied, for example, in wafer-level package (WLP) or panel-level package (PLP) processes, either chip first or chip last (RDL first).

The electronic device of the present disclosure may include an electronic unit. The electronic unit may include passive elements, active elements, or a combination of the foregoing, such as capacitors, resistors, inductors, varactor diodes, variable capacitors, filters, diodes, transistors, sensors, microelectromechanical system (MEMS) elements, liquid crystal chips, etc., but are not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or any combination of the foregoing, but are not limited thereto. The sensors may include, for example, capacitive sensors, optical sensors, electromagnetic sensors, fingerprint sensors (FPS), touch sensors, antennas, or pen sensors, etc., but are not limited to thereto.

It should be understood that according to the embodiments of the present disclosure, the depth, thickness, width or height of each element, or the space of the elements or the distance between them may be measured using an optical microscope (OM), a scanning electron microscope (SEM), a film thickness profile measuring gauge (a-step), an elliptical thickness gauge, or other suitable measurement methods. According to some embodiments, a scanning electron microscope may be used to obtain a cross-sectional structural image including the elements to be measured, and to measure the depth, thickness, width or height of each element, or the space or distance between the elements.

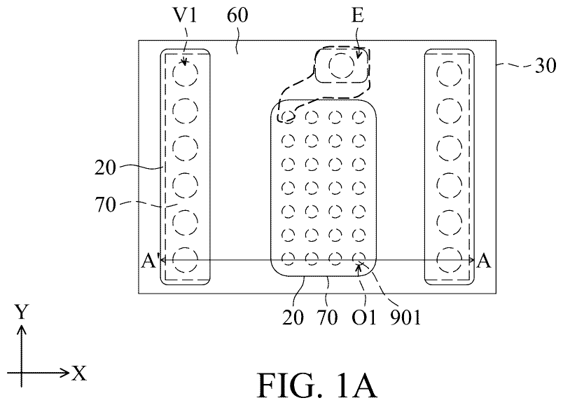

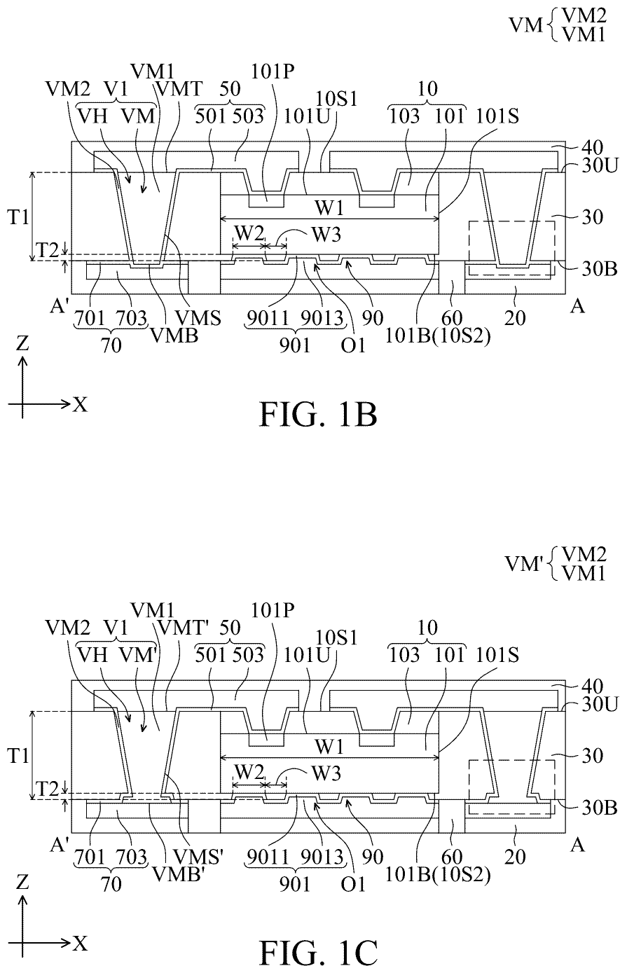

An embodiment of the disclosure is to provide an electronic device. FIG. 1A is a plan view of an electronic device according to an embodiment of the present disclosure. FIG. 1B is a cross-sectional schematic view of the electronic device shown in FIG. 1A taken along a line AA′ according to an embodiment of the present disclosure. The term “cross-sectional schematic view” used herein refers to a schematic view taken along a normal direction (i.e., Z direction) of the electronic device.

The electronic device of the present disclosure includes an electronic unit 10 having a first side 10S1 and a second side 10S2 opposite the first side 10S1; an encapsulation layer 30 surrounding the electronic unit 10 and having a plurality of openings O1 exposing the second side 10S2 of the electronic unit 10; a first circuit structure 50 disposed on the first side 10S1 of the electronic unit 10 and electrically connected to the electronic unit 10; a second circuit structure 70 disposed on the second side 10S2 of the electronic unit 10; a via V1 penetrating through the encapsulation layer 30 and electrically connected to the first circuit structure 50 and the second circuit structure 70; and a heat dissipation layer 90 disposed on the second side 10S2 of the electronic unit 10, wherein the heat dissipation layer 90 contacts the electronic unit 10 through the plurality of openings O1.

The electronic unit 10 may include a chip 101 and a protective layer 103. The chip 101 may include an active surface 101U, a back surface 101B opposite the active surface 101U, and a side surface 101S of the chip 101 connecting the active surface 101U and the back surface 101B. In some embodiments, the back surface 101B of the chip 101 and the second side 10S2 of the electronic unit 10 may be shown as the same line in FIG. 1B, but the disclosure is not limited thereto. The back surface 101B of the chip 101 has a back surface width W1 in a first direction (e.g., the X direction) perpendicular to the normal direction of the electronic device. An input/output pad (I/O pad) 101P may be disposed on the active surface 101U of the chip 101. The protective layer 103 is disposed on the active surface 101U of the chip 101 and exposes the input/output pad 101P.

In some embodiments, the chip 101 may include a chip made of silicon (Si), gallium arsenide (GaAs), gallium nitride (GaN), silicon carbide (SiC), sapphire or a glass substrate, but is not limited thereto. In some embodiment, the chip 101 may include a semiconductor packaging element, such as a ball grid array (BGA) packaging element, a chip size package (CSP) element, a flip chip or a 2.5D/3-dimensional (2.5D/3D) semiconductor packaging element, but the disclosure is not limited thereto. In some embodiment, the chip 101 may include a flip-chip bonding element, such as an integrated circuit (IC), a transistor, a controlled silicon rectifier, a valve, a thin film transistor, a capacitor, an inductor, a variable capacitor, a filter, a resistor, a diode, a microelectromechanical system (MEMS) element, a liquid crystal chip, a semiconductor structure, or any combination of the foregoing, but the disclosure is not limited thereto. In addition, the chip 101 may be a known good die (KGD), which may include various electronic elements, such as (but not limited to) wires, transistors, circuit boards, or any combination of the foregoing. In some embodiments, multiple chips may be included, wherein adjacent chips may have different functions, such as, but are not limited to, integrated circuits, RFICs, and D-RAMs.

In some embodiments, the protective layer 103 may include a nitride, an oxide, a nitrogen oxide, a perfluoroalkoxyalkane (PFA), an epoxy, an Ajinomoto build-up film (ABF), a polybenzoxazole (PBO), a photosensitive polyimide (PSPI), a polyamide (PI), other suitable materials, or a combination thereof, but the disclosure is not limited thereto. In some embodiments, the protective layer 103 may include an organic material, an inorganic material, or other suitable insulating material, such as, but not limited to, an epoxy, a silicon nitride (SiNx), a silicon oxide (SiOx), or a combination thereof, but the disclosure is not limited thereto. In some embodiments, the protective layer 103 may be a stack including a plurality of layers, such as a stack including at least one inorganic material layer and at least one organic material layer, wherein the inorganic material layer is disposed between the organic material layer and the chip 101. In some embodiments, a coefficient of thermal expansion (CTE) of the protective layer 103 may be 0.1-50 ppm/C, or 0.1-30 ppm/C. A Young's modulus of the protective layer 103 may be 3-15 Gpa, and/or a tensile strength of the protective layer 103 may be 50-110 Mpa. In some embodiments, the protective layer 103 may include a filler having a particle size between 0.05 and 20 μm.

The encapsulation layer 30 having the openings O1 surrounds the electronic unit 10. In the cross-sectional schematic view of the electronic device shown in FIG. 1B, the encapsulation layer 30 is in direct or indirect contact with at least the side surface 101S of the chip 101. In some embodiments, the encapsulation layer 30 is in direct or indirect contact with the back surface 101B of the chip 101. In some embodiments, the encapsulation layer 30 covers the side surface 101S and a portion of the back surface 101B of the chip 101 and exposes the active surface 101U. In some embodiments, the encapsulation layer 30 may comprise an organic material, an inorganic material, or other suitable insulating materials, such as, but not limited to, an epoxy, a polymer, a photosensitive polyimide (PSPI), a polyimide (PI), a silicon nitride (SiNx), a silicon oxide (SiOx), or a combination thereof, but the disclosure is not limited thereto. In some embodiments, the encapsulation layer 30 may include a filler having a particle size between 0.1 and 50 μm. The encapsulation layer 30 surrounding the electronic unit may reduce the effects of ambient water and oxygen on the electronic device, but the disclosure is not limited thereto.

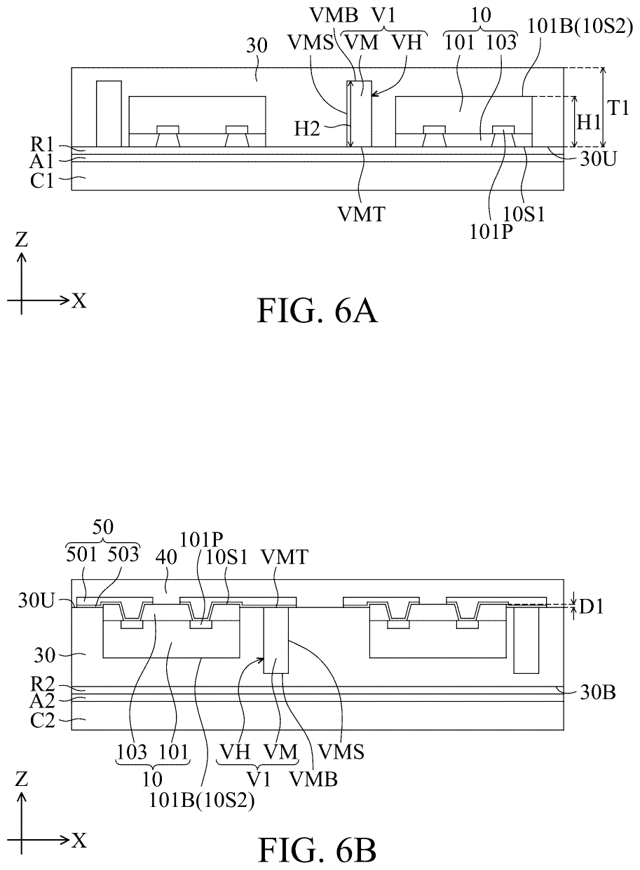

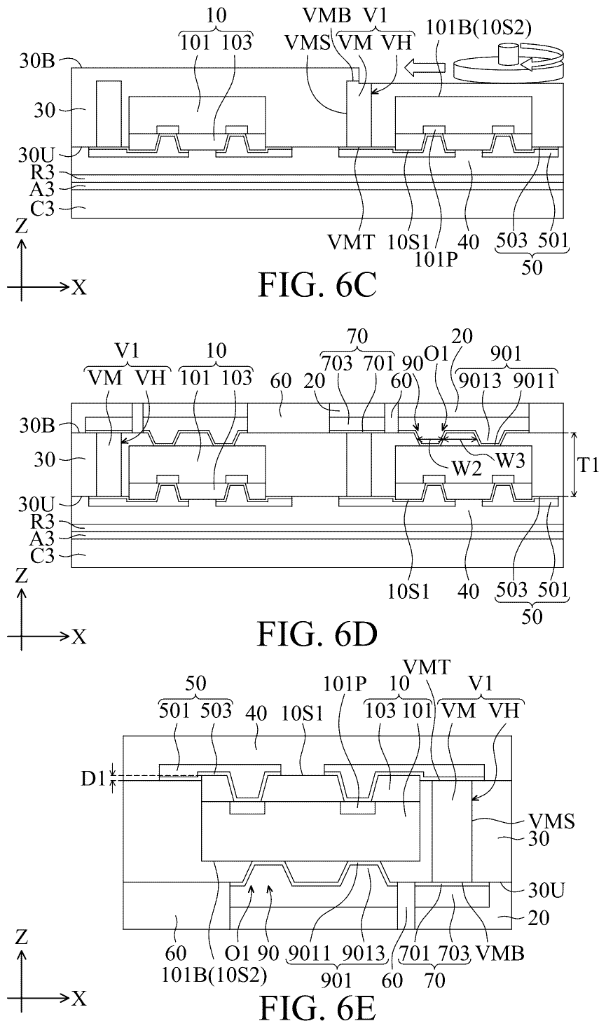

The encapsulation layer 30 may have an upper surface 30U and a bottom surface 30B opposite the upper surface 30U. The bottom surface 30B of the encapsulation layer 30 may be adjacent to the back surface 101B of the chip 101. In some embodiments, the back surface 101B of the chip 101 may be between the bottom surface 30B of the encapsulation layer 30 and the active surface 101U of the chip 101. In some embodiments, the upper surface 30U of the encapsulation layer 30 and the first side 10S1 of the electronic unit 10 may be spaced apart by a step difference D1 in the Z-direction (see FIGS. 6B to 6E) to reduce a risk of delamination of the first circuit structure 50 formed on the upper surface 30U of the encapsulation layer 30. In some embodiments, the step difference D1 may be between 1 and 10 μm, but the disclosure is not limited thereto. In some embodiments, the encapsulation layer 30 has a thickness T1 in the normal direction of the electronic device (i.e., the Z-direction). That is, in the Z-direction, the upper surface 30U and the bottom surface 30B of the encapsulation layer 30 are spaced apart by a first distance and the first distance is equal to the thickness T1. In some embodiments, the encapsulation layer 30 on and covering the back surface 101B of the chip 101 has a thickness T2. That is, the bottom surface 30B of the encapsulation layer 30 and the back surface 101B of the chip 101 are spaced apart by a second distance and the second distance is equal to the thickness T2. The openings O1 extends from the bottom surface 30B of the encapsulation layer 30 to the back surface 101B of the chip 101 and exposes a portion of the back surface 101B of the chip 101, as shown in FIGS. 1A and 1B. In some embodiments, the thickness T2 is approximately equal to the second distance and approximately equal to an opening depth of the openings O1. In the embodiment, each opening O1 has an opening width W2 in a first direction (i.e., the X direction) and an opening depth in the normal direction of the electronic device (i.e., the Z direction), wherein the opening depth is approximately equal to the thickness T2. In some embodiments, two of the openings O1 are spaced apart from each other by a space W3. In some embodiments, the opening width W2>the space W3. In some embodiments, the opening width W2 and the space W3 satisfy to the following formula:

¼*the opening width W2≤the space W3≤¾*the opening width W2.

The heat dissipation layer 90 is filled into the openings O1 and contacts the back surface 101B of the chip 101 through the openings O1. In some embodiments, a portion of the encapsulation layer 30 is between the chip 101 and the heat dissipation layer 90. The thickness T2 of the portion of the encapsulation layer 30 and the thickness T1 of the encapsulation layer 30 have a ratio (the thickness T2/the thickness T1) of 0.01-0.5, i.e., 0.01≤T2/T1≤0.5./T1≤0.5. Through the use of the above structure, the heat dissipation efficiency of the heat dissipation layer 90 can be improved, or the risk of delamination of the encapsulation layer 30 and the chip 101 can be reduced, or the risk of warpage of the electronic device can be reduced, but the disclosure is not limited thereto. In some embodiments, the heat dissipation layer 90 may have a plurality of heat dissipation patterns 901, and each heat dissipation pattern 901 may be filled into one of the openings O1 of the encapsulation layer 30 and in contact with the back surface 101B of the chip 101, as shown in FIG. 1A and FIG. 1B. In the embodiment, a contact width of the heat dissipation pattern 901 in each opening O1 contacting the back surface 101B of the chip 101 is approximately equal to the opening width W2 of the opening O1, and a thickness of the heat dissipation pattern 901 in the Z-direction is approximately equal to the opening depth of the opening O1. In some embodiments, the sum of the contact widths of the heat dissipation layer 90 contacting the back surface 101B of the chip 101 is equal to the sum of the opening widths W2 of the openings O1. The ratio of the sum of the contact widths of the heat dissipation layer 90 contacting the back surface 101B of the chip 101/the back surface width W1 of the back surface 101B of the chip 101 may be between 0.2 and 0.7. In the embodiment, the heat dissipation layer 90 of the electronic device of the disclosure can fully perform a function of heat dissipation. In the embodiment, a surface the heat dissipation pattern 901 away from the second side may also patterned into fin type to improve heat dissipation. Alternatively, through the use of the above structure, the back surface 101B of the chip 101 can be prevented from contacting with a metal over a large area and a probability of a mismatch in thermal expansion coefficients between the chip 101 and the metal can be reduced. Therefore, a probability of warping of the chip 101 can be reduced or a risk of breakage caused by insufficient area of a bonding area between the encapsulation layer 30 and the chip 101 can be reduced, thereby providing the electronic device having good heat dissipation and reliability.

The heat dissipation layer 90 may include a single layer structure or a multi-layer structure having multiple layers. For example, in some embodiments, the heat dissipation layer 90 may be a multi-layer structure including a first sublayer 9011 and a second sublayer 9013. The first sublayer 9011 may be disposed between the second sublayer 9013 and the back surface 101B of the chip 101, but the disclosure is not limited thereto. In some embodiments, the heat dissipation layer 90 may be a single-layer structure including a second sublayer 9013. In some embodiments, the thermal conductivity of the heat dissipation layer 90 may be greater than or equal to 10 W/mK and less than or equal to 505 W/mK. That is, the heat dissipation layer 90 may include any material having a thermal conductivity greater than or equal to 10 W/mK and less than or equal to 505 W/mK. In some embodiments, the first sublayer 9011 may include a seed layer, a metal, or a combination thereof. In some embodiments, examples of the metal may include a copper (Cu), an aluminum (Al), a molybdenum (Mo), a tungsten (W), a gold (Au), a chromium (Cr), a nickel (Ni), a platinum (Pt), a titanium (Ti), a silver (Ag), a tantalum (Ta), a nitride, other suitable metallic materials, or a combination thereof, but the disclosure is not limited thereto. In some embodiments, the second sublayer 9013 may include a metal. Examples of the metal are described above and are not repeated herein. In some embodiments, the thermal conductivity of the first sublayer 9011 may be different from the thermal conductivity of the second sublayer 9013. For example, the thermal conductivity of the first sublayer 9011 is less than the thermal conductivity of the second sublayer 9013, wherein the thermal conductivity of the first sublayer 9011 may be greater than or equal to 10 W/mK or less than or equal to 50 W/mK and the thermal conductivity of the second sublayer 9013 may be greater than or equal to 50 W/mK or less than or equal to 505 W/mK.

The first circuit structure 50 may be disposed on the first side 10S1 of the electronic unit 10, the upper surface 30U of the encapsulation layer 30, and the via V1. The first circuit structure 50 may include a single layer structure or a multi-layer structure having multiple layers. For example, in some embodiments, the first circuit structure 50 may be a multilayer structure including at least a first conductive layer 501 and at least a second conductive layer 503. The first conductive layer 501 may be disposed between the second conductive layer 503 and the input/output pad 101P and electrically connect the second conductive layer 503 and the input/output pad 101P, but the disclosure is not limited thereto. In some embodiments, the first circuit structure 50 may be electrically connected to a pad E of the chip 101, wherein the pad E may be, for example, a source, a gate, or a drain, as shown in FIG. 1A. In some embodiments, the first circuit structure 50 may be a single layer structure including a second conductive layer 503. The first conductive layer 501 may include a seed layer, a metal, or a combination thereof. In some embodiments, the second conductive layer 503 may include a metal. Examples of the metal are described above and are not repeated herein.

The second circuit structure 70 is disposed on the second side 10S2 of the electronic unit 10. In some embodiments, the second circuit structure 70 and the heat dissipation layer 90 may be formed in the same process to simplify the process of the electronic device of the present disclosure. In detail, the second circuit structure 70 and the heat dissipation layer 90 may be formed in the same process. That is, the second circuit structure 70 and the heat dissipation layer 90 may be formed in one piece, but the disclosure is not limited thereto. In some embodiments, the second circuit structure 70 is electrically connected to the heat dissipation layer 90. In some embodiments, the second circuit structure 70 is electrically insulated from the heat dissipation layer 90. The second circuit structure 70 may include a single-layer structure or a multi-layer structure having multiple layers. For example, in some embodiments, the second circuit structure 70 may be a multi-layer structure including at least a third conductive layer 701 and at least a fourth conductive layer 703. The third conductive layer 701 may be disposed between the fourth conductive layer 703 and the bottom surface 30B of the encapsulation layer 30. In some embodiments, the second circuit structure 70 may be a single layer structure including a fourth conductive layer 703. The third conductive layer 701 may include a seed layer, a metal, or a combination thereof. In some embodiments, the fourth conductive layer 703 may include a metal. Examples of the metal are described above and are not repeated herein. The multi-layer structure of the second circuit structure 70, including, for example, a seed layer, may improve adhesion between the subsequently formed conductive layer and the insulating layer, but the disclosure is not limited thereto. The circuit structure in the present disclosure may be a redistribution layer (RDL), which may enable redistribution of circuits in the electronic device and/or further increase a fan-out area of the circuits, or different electronic elements may be electrically interconnected by the first circuit structure 50 or the second circuit structure 70. For example, a space between two adjacent contact pads at an end of the first circuit structure 50 contacting the chip 101 may be less than or equal to a space between two adjacent contact pads at an end of the first circuit structure 50 way from the chip 101. Therefore, the first circuit structure 50 may adjust a fan-out condition of a circuit, but the disclosure is not limited thereto.

The via V1 includes a through-hole opening VH penetrating the encapsulation layer 30 and a conductive element VM disposed in the through-hole opening VH. The via V1 may electrically connect the first circuit structure 50 and the second circuit structure 70 by the conductive element VM. The conductive element VM may have a bottom portion VMB adjacent to the second circuit structure 70, a top portion VMT adjacent to the first circuit structure 50, and a side VMS connecting the bottom portion VMB and the top portion VMT. In some embodiments, the bottom portion VMB of the conductive element VM may protrude out of the through-hole opening VH. That is, the bottom portion VMB of the conductive element VM may protrude from the bottom surface 30B of the encapsulation layer 30. In other words, the via V1 may have a bottom portion, a top portion, and a side connecting the bottom portion and the top portion, wherein the bottom portion of the via V1 connects the second circuit structure 70 and the bottom portion protrudes from the bottom surface 30B of the encapsulation layer 30. In the embodiment, the bottom surface 30B of the encapsulation layer 30 may be between the bottom portion VMB of the conductive element VM and the second side 10S2 of the electronic unit 10, as shown in FIG. 1B, but the disclosure is not limited thereto. In some embodiments, in a cross-sectional schematic view of the electronic device, the side VMS of the conductive element VM may include a sloping edge, as shown in FIG. 1B, but the disclosure is not limited thereto. In some embodiments, in a cross-sectional schematic view of the electronic device, the side VMS of the conductive element VM may include a stepped edge, as shown in a dashed box in FIG. 1C. The conductive element VM may include a single layer structure or a multi-layer structure having multiple layers. In some embodiments, the conductive element VM may be a multi-layer structure including a conductive layer VM2 and a conductive metal layer VM1. The conductive layer VM2 may be disposed between the conductive metal layer VM1 and the encapsulation layer 30. In some embodiments, the conductive element VM may be a single layer structure including the conductive metal layer VM1. The conductive layer VM2 may include a seed layer, a metal, or a combination thereof. In some embodiments, the conductive metal layer VM1 may include a metal. Examples of the metal are described above and are not repeated herein. In some of the embodiments, a thermal conductivity of the conductive element VM is greater than 100 (Wm−1K−1). In other words, the conductive element VM may improve thermal performance of the electronic device.

In some embodiments, the electronic device may further include a bonding layer 20 on the second circuit structure 70. The electronic device may be electrically connected to other electronic devices by the bonding layer 20. In some embodiments, the bonding layer 20 may be disposed on a top surface of the second circuit structure 70. That is, in the Z-direction, the second circuit structure 70 may be disposed between the bonding layer 20 and the second side 10S2 of the electronic unit 10, but the disclosure is not limited thereto. In some embodiments, the bonding layer 20 may be disposed on a side surface of the second circuit structure 70 to enable side electrical connections. The bonding layer 20 may include a tin (Sn), a gold (Au), a nickel (Ni), other suitable metallic materials, alloys thereof, or a combination thereof, but the disclosure is not limited thereto. Examples of the other electronic devices may include, but are not limited to, printed circuit boards, flexible circuit boards, flexible printed circuit boards, or a combination thereof.

In some embodiments, the electronic device may further include a first protective layer 40 on the first circuit structure 50. The first protective layer 40 may cover the first circuit structure 50 to reduce a risk of oxidation of the first circuit structure 50, as shown in FIG. 1B. The first protective layer 40 may include an organic material, an inorganic material, or other suitable insulating material, such as (but not limited to) a resin, an Ajinomoto build-up film, a polybenzoxazole, a photosensitive polyimide, a polyimide, a silicon nitride, a silicon oxide, or a combination thereof, without limitation to the present disclosure.

In some embodiments, the electronic device may further include a second protective layer 60 disposed on the bottom surface 30B of the encapsulation layer 30. For example, the second protective layer 60 contacts a portion of the bottom surface 30B of the encapsulation layer 30 and is disposed on the second side 10S2 of the electronic unit 10. The second protective layer 60 may surround the second circuit structure 70 to reduce a risk of oxidation of the second circuit structure 70, as shown in FIG. 1A. The second protective layer 60 is in direct or indirect contact with at least a side surface of the second circuit structure 70. In some embodiments, the second protective layer 60 may be in direct contact with a side surface of the second circuit structure 70, as shown in FIG. 1B, but the disclosure is not limited thereto. In some embodiments, the second protective layer 60 and the side surfaces of the second circuit structure 70 may be in indirect contact each other by sandwiching the space between them. The second protective layer 60 may include an organic material, an inorganic material, or other suitable insulating materials, such as, but not limited to, a resin, an Ajinomoto build-up film, a polybenzoxazole, a photosensitive polyimide, a polyimide, a silicon nitride, a silicon oxide, or a combination thereof, but the disclosure is not limited thereto.

FIG. 1C is a cross-sectional schematic view of the electronic device shown in FIG. 1A taken along a line AA′ according to another embodiment of the present disclosure. The structure of the electronic device shown in FIG. 1C is substantially the same as that of the electronic device shown in FIG. 1B except for the conductive element VM′, so only the conductive element VM′ is described below.

As shown in FIG. 1C, the conductive element VM′ includes a bottom portion VMB′ adjacent to the second circuit structure 70, a top portion VMT′ adjacent to the first circuit structure 50, and a side VMS' connecting the bottom portion VMB′ and the top portion VMT′. In some embodiments, the bottom portion VMB′ of the conductive element VM′ may protrude out of the through-hole opening VH. That is, the bottom portion VMB′ of the conductive element VM′ may protrude from the bottom surface 30B of the encapsulation layer 30. In the embodiment, the bottom surface 30B of the encapsulation layer 30 may be between the bottom portion VMB′ of the conductive element VM′ and the second side 10S2 of the electronic unit 10, as shown in FIG. 1C, but the disclosure is not limited thereto. In some embodiments, in a cross-sectional schematic view of the electronic device, the side VMS' of the conductive element VM′ includes a stepped edge, as shown in a dotted box, and the stepped edge is adjacent to the second circuit structure 70, as shown in FIG. 1C, but the disclosure is not limited thereto. In other words, in the embodiment, the via V1 including the conductive element VM′ may have a bottom portion, a top portion, and a side connecting the bottom portion and the top portion, wherein the bottom of the via V1 is connected to the second circuit structure 70, and the side of the via V1 includes a stepped edge. Membrane layers are not coplanar due to the stepped edge and therefore their contact area can be increased to improve the adhesion between them, but the disclosure is not limited thereto.

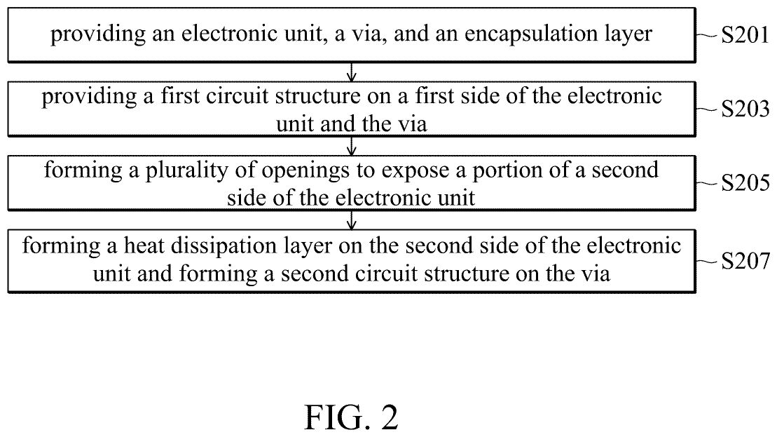

Another aspect of the disclosure is to provide a method of manufacturing an electronic device. FIG. 2 is a flowchart of a method of manufacturing an electronic device according to an embodiment of the present disclosure. As shown in FIG. 2, the method of manufacturing an electronic device according to an embodiment of the present disclosure includes: a step S201 of providing an electronic unit, a via, and an encapsulation layer; a step S203 of providing a first circuit structure on a first side of the electronic unit and the via; a step S205 of forming a plurality of openings to expose a portion of a second side of the electronic unit; and a step S207 of forming a heat dissipation layer on the second side of the electronic unit and forming a second circuit structure on the via. The electronic unit provided in step S201 is adjacent to the via, and the encapsulation layer surrounds the electronic unit and the via and exposes the first side of the electronic unit and a top portion of a conductive element of the via. The first circuit structure provided in step S203 is disposed on the first side of the electronic unit and the top portion of the conductive element and electrically connects the electronic unit and the via. The second circuit structure formed in step S207 electrically connects the first circuit structure through the via.

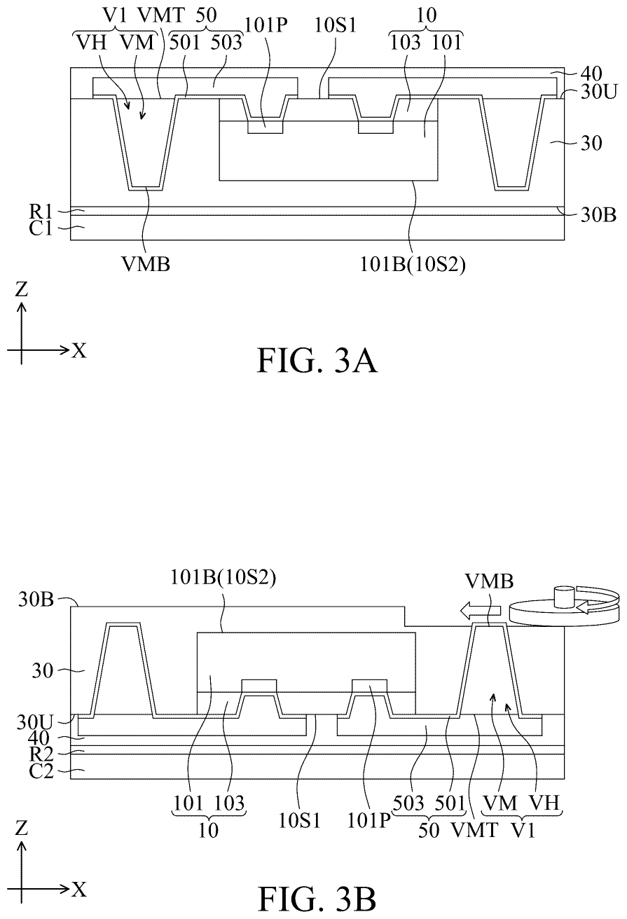

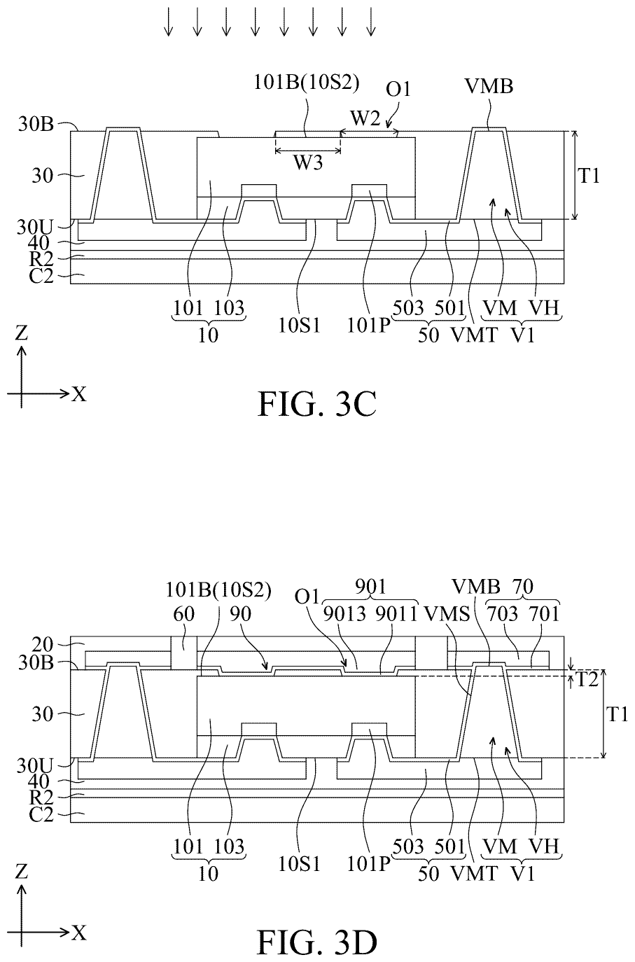

FIGS. 3A to 3D are schematic views of semi-finished products of an electronic device during manufacture of the electronic device according to an embodiment of the present disclosure. The method of manufacturing the electronic devices disclosed herein is further described below in conjunction with FIG. 2 and FIGS. 3A to 3D.

Step S201 of providing the electronic unit, the via, and the encapsulation layer may include an electronic unit providing process to provide the electronic unit 10 on a carrier substrate, an encapsulation layer formation process to form the encapsulation layer 30, and a via formation process to form the via V1. In some embodiments, step S201 may include sequentially performing the electronic unit providing process, the encapsulation layer formation process, and the via formation process, but the disclosure is not limited thereto. In some embodiments, step S201 may include sequentially performing the electronic unit providing process, the via formation process, and the encapsulation layer formation process. The embodiment in which step S201 including sequentially performing the electronic unit providing process, the encapsulation layer formation process, and the via formation process is described below in conjunction with FIG. 3A.

In the embodiment, the electronic unit providing process may including disposing the electronic unit 10 having a first side 10S1 and a second side 10S2 opposite the first side 10S1 on the carrier substrate. In some embodiments, the electronic unit 10 may be disposed on the carrier substrate such that the first side 10S1 faces the carrier substrate, i.e. disposed in a face down process, but the disclosure is not limited thereto. In some embodiments, the electronic unit 10 may be disposed on the carrier substrate such that the second side 10S2 faces the carrier substrate, i.e., disposed in a face up process. The encapsulation layer formation process may include forming the encapsulation layer 30 on the carrier substrate and surrounding the electronic unit 10. In the embodiment, the encapsulation layer 30 is in direct or indirect contact with the second side 10S2 of the electronic unit 10 and a side of the electronic unit 10. The via formation process may include forming a through-hole opening VH next to the electronic unit 10 and filling the conductive element VM in the through-hole opening VH to form the via V1 after inverting the electronic unit 10 and the encapsulation layer 30 surrounding the electronic unit 10 onto a carrier substrate C1 on which a release layer R1 is disposed to expose the first side 10S1 of the electronic unit 10. In some embodiments, the through-hole opening VH may be formed by a laser perforation process, a mechanical perforation process, and/or a photolithography process. In some embodiments, the conductive element VM may be filled into the through-hole opening VH by an electroplating process, a chemical plating process, and/or a sputtering process. In the embodiment, the encapsulation layer 30 surrounds the electronic unit 10 and the via V1 and exposes the first side 10S1 of the electronic unit 10 and a top portion VMT of the conductive element VM of the via V1, the resulting structure is shown in FIG. 3A.

In step S203, the first circuit structure 50 including the first conductive layer 501 and the second conductive layer 503 may be provided on the input/output pads 101P and the first side 10S1 of the electronic unit 10 and on the top portion VMT of the via V1 exposed by the encapsulation layer 30 to electrically connect the electronic unit 10 and the via V1. In some embodiments, step S203 may include a plating process, a chemical plating process, and/or a sputtering process. In some embodiments, the method of manufacturing the electronic device of the present disclosure may further include a first protective layer formation step of forming a first protective layer 40 on the first circuit structure 50 to reduce a risk of oxidation of the first circuit structure 50. The structure obtained after the first protective layer formation step is shown in FIG. 3A, but the disclosure is not limited thereto. In some embodiments, the first protective layer 40 may be omitted.

Step S205 of forming the openings to expose the second side of the electronic unit may include an encapsulation layer removal step to remove a portion of the encapsulation layer 30 and an opening etching step to form the openings O1. In some embodiments, the encapsulation layer removal step is performed until the conductive element VM of the via V1 is exposed, but the disclosure is not limited thereto. In some embodiments, the bottom portion VMB of the conductive element VM is still covered by the encapsulation layer 30 after the encapsulation layer removal step.

The following further illustrates an embodiment in which the encapsulation layer removal step in step S205 is performed until the conductive element VM is exposed in conjunction with FIG. 2 and FIGS. 3B to 3D. Before performing step S205, the structure obtained from step S203 is inverted onto a carrier substrate C2 on which a release layer R2 is provided, and the release layer R1 and the carrier substrate C1 are removed to expose the bottom surface 30B of the encapsulation layer 30. The encapsulation layer removal step is performed in step S205, and a portion of the encapsulation layer 30 is removed until a conductive element VM is exposed, as shown in FIG. 3B. The encapsulation layer removal step may include a grinding process. The opening etching step, as shown by arrows in FIG. 3C, is performed after the encapsulation layer removal step. In some embodiments, the opening etching step may include a first etching process to etch the encapsulation layer 30 surrounding the conductive element VM and a second etching process to partially etch a portion of the encapsulation layer 30 on the back surface 101B of the chip 101. The first etching process may cause the bottom portion VMB of the conductive element VM to protrude from the encapsulation layer 30 to reduce a risk of delamination of layers subsequently formed thereon. The second etching process may form a plurality of openings O1 exposing the back surface 101B of the chip 101. In some embodiments, the first etching process may be omitted. In some embodiments, the encapsulation layer 30 may have a thickness T1 in the Z-direction after the first etching process. In some embodiments, the openings O1 formed by the second etching process may have an opening width W2 in the first direction (i.e., the X-direction) and an opening depth in the normal direction of the electronic device (i.e., the Z-direction). In some embodiments, two of the openings O1 are spaced apart from each other by a space W3. In some embodiments, the opening width W2>the space W3. In some embodiments, the opening width W2 and the space W3 satisfy to the following formula:

¼*the opening width W2≤the space W3≤¾*the opening width W2.

In some embodiments, the first etching process may include a plasma etching process, a laser etching process, a chemical etching process, other suitable etching process, or a combination thereof, but the disclosure is not limited thereto. In some embodiments, the second etching process may include a laser perforation process, a mechanical perforation process, a photolithography process, other suitable etching processes, or a combination thereof, but the disclosure is not limited thereto.

The heat dissipation layer 90 and the second circuit structure 70 are formed on the second side 10S2 of the electronic unit 10 and the via V1 in step S207. In some of the embodiments, a roughness of the second side 10S2 is less than or equal to 1 μm, 0.5 μm or 0.3 μm, to increase adhesion, but not limited thereto. The heat dissipation layer 90 is between the second circuit structure 70 and the second side 10S2 of the electronic unit 10. The via V1 electrically connects the second circuit structure 70 and the first circuit structure 50, and the resulting structure is shown in FIG. 3D. The heat dissipation layer 90 may include a plurality of heat dissipation patterns 901 filled into the plurality of openings O1 formed in step S205 and contacting the back surface 101B of the chip 101 through the openings O1. The sum of the contact widths of the heat dissipation layer 90 contacting the back surface 101B of the chip 101 is equal to the sum of the opening widths W2 of the openings O1. In some embodiments, the ratio of the sum of the contact widths of the heat dissipation layer 90 contacting the back surface 101B of the chip 101/the back surface width W1 of the back surface 101B of the chip 101 may be between 0.2 and 0.7. The encapsulation layer 30 disposed between the chip 101 and the second circuit structure 70 has a thickness T2 that is approximately equal to the opening depth of the opening O1. In some embodiments, the thickness T2/the thickness T1 may range from 0.01-0.5.

In some embodiments, the heat dissipation layer 90 and the second circuit structure 70 may be formed separately by different processes. In some embodiments, the heat dissipation layer 90 and the second circuit structure 70 in step S207 may be formed by the same process. Specifically, in some embodiments, the heat dissipation layer 90 and the second circuit structure 70 may be obtained by patterning a metal layer after depositing the metal layer on the second side 10S2 of the electronic unit 10 and on the bottom portion VMB of the conductive element VM, but the disclosure is not limited thereto. In some embodiments, a thickness of the deposited metal layer in the Z-direction is greater than the opening depth of the opening O1.

In some embodiments, the method of manufacturing the electronic device of the present disclosure may further include a bonding layer formation step of disposing a bonding layer 20 on the second circuit structure 70 to electrically connect to other electronic devices, and a second protective layer formation step of disposing a second protective layer 60 surrounding the second circuit structure 70 on the second side 10S2 of the electronic unit 10 to reduce a risk of oxidation of the second circuit structure 70. The structure obtained after the bonding layer formation step and the second protective layer formation step is shown in FIG. 3D, but the disclosure is not limited thereto. In some embodiments, the bonding layer 20 and/or the second protective layer 60 may be omitted.

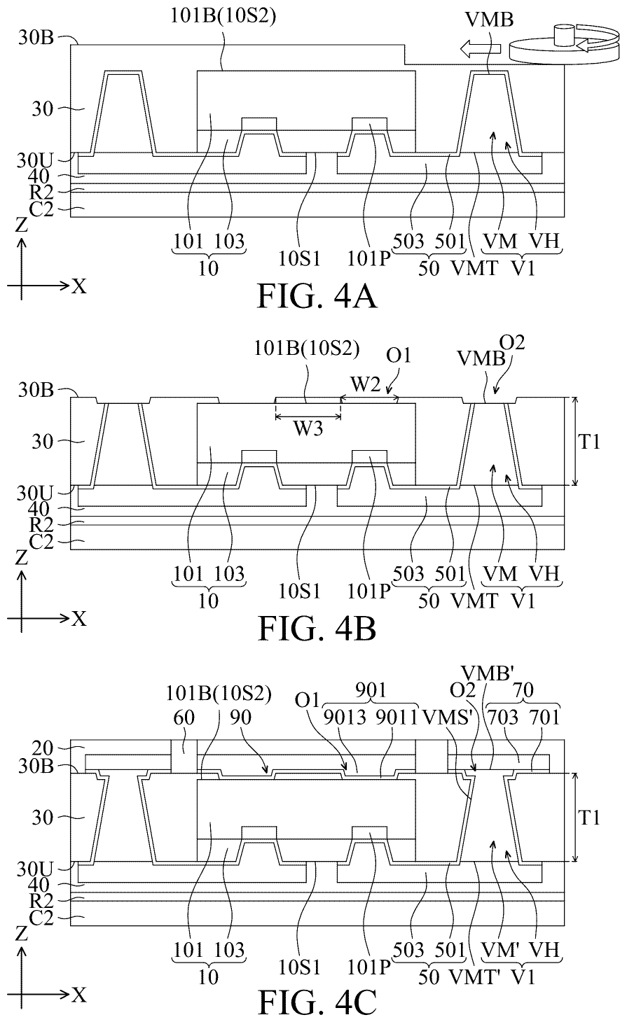

FIGS. 4A to 4C are schematic views of semi-finished products of an electronic device during manufacture of the electronic device according to another embodiment of the present disclosure. Specifically, FIGS. 4A to 4C illustrate an embodiment in which the bottom portion VMB of the conductive element VM is still covered by the encapsulation layer 30 after the encapsulation layer removal step. An embodiment in which the bottom portion VMB of the conductive element VM is still covered by the encapsulation layer 30 after the encapsulation layer removal step is illustrated below in conjunction with FIG. 2 and FIGS. 4A to 4C.

After performing the encapsulation layer removal step in step S205, the bottom portion VMB of the conductive element VM is still covered by the encapsulation layer 30, as shown in FIG. 4A. In the embodiment, the bottom portion VMB of the conductive element VM is protected by the encapsulation layer 30 during the encapsulation layer removal step, thereby reducing a risk of material smearing of the conductive element VM. The opening etching step is performed after the encapsulation layer removal step. In some embodiments, the opening etching step may include a third etching process of partially etching the encapsulation layer 30 on the bottom portion VMB of the conductive element VM and a portion of the encapsulation layer 30 on the back surface 101B of the chip 101. The third etching process may form a plurality of openings O1 exposing the back surface 101B of the chip 101 and openings O2 exposing the bottom portion VMB of the conductive element VM. The structure obtained after the opening etching step may be shown in FIG. 4B. In some embodiments, the encapsulation layer 30 may have a thickness T1 in the Z-direction. In some embodiments, the opening O1 has an opening width W2 in the first direction (i.e., the X-direction) and an opening depth in the normal direction of the electronic device (i.e., the Z-direction). In some embodiments, a width of the opening O2 in the first direction (i.e., the X direction) is greater than a width of the bottom portion VMB of the conductive element VM in the first direction, but the disclosure is not limited thereto. In some embodiments, a depth of the opening O2 in the normal direction of the electronic device (i.e., the Z-direction) is approximately equal to the opening depth of the opening O1, but the disclosure is not limited thereto. In some embodiments, the third etching process may include a laser perforation process, a mechanical perforation process, a photolithography process, another suitable etching process, or a combination thereof, but the disclosure is not limited thereto.

The heat dissipation layer 90 and the second circuit structure 70 are formed on the second side 10S2 of the electronic unit 10 and the via V1 in step S207. The heat dissipation layer 90 is between the second circuit structure 70 and the second side 10S2 of the electronic unit 10 and the via V1 electrically connects the second circuit structure 70 and the first circuit structure 50, the resulting structure is shown in FIG. 4C. In the embodiment, a portion of a metal layer of the second circuit structure 70 is filled into the opening O2 during forming the second circuit structure 70, and a new conductive element VM′ is formed together with the conductive element VM. The side VMS' of the conductive element VM′ may have a stepped edge. Except for forming the new conductive element VM′, step S207 in the embodiment is substantially the same as step S207 described above, and therefore will not be repeated herein.

In some embodiments, the method of manufacturing the electronic device of the present disclosure may further include a bonding layer formation step of disposing a bonding layer 20 on the second circuit structure 70 to electrically connect with other electronic devices, and a second protective layer formation step of disposing a second protective layer 60 surrounding the second circuit structure 70 on the second side 10S2 of the electronic unit 10 to reduce a risk of oxidation of the second circuit structure 70. The structure obtained after the bonding layer formation step and the second protective layer formation step is shown in FIG. 4C, but the disclosure is not limited thereto. In some embodiments, the bonding layer 20 and/or the second protective layer 60 may be omitted.

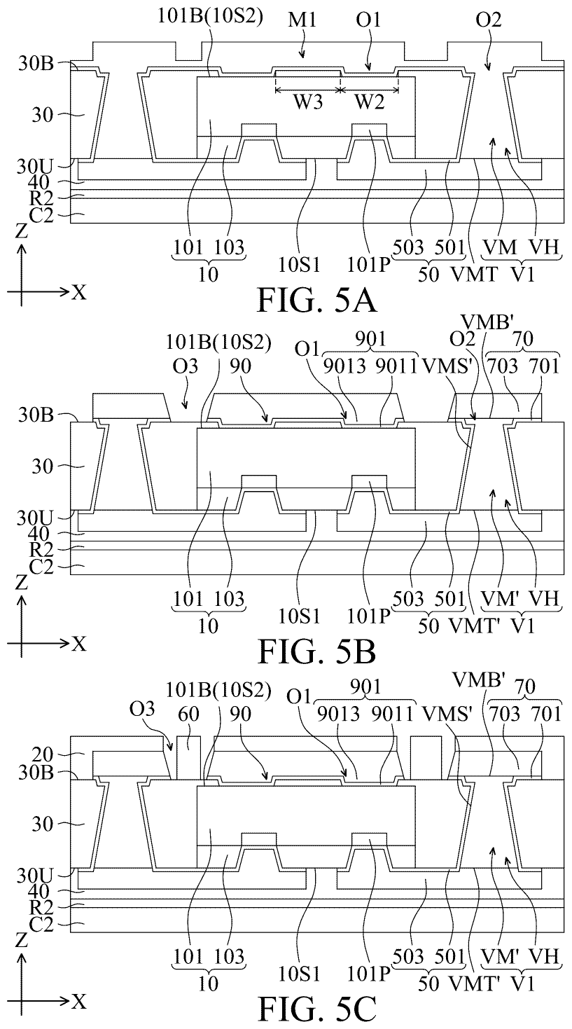

FIGS. 5A to 5C are schematic views of semi-finished products of an electronic device during manufacture of the electronic device according to an embodiment of the present disclosure. Specifically, FIGS. 5A to 5C are views illustrating step S207 in the method of manufacturing the electronic device of an embodiment of the present disclosure.

FIG. 5A illustrates an embodiment in which step S207 is performed on the structure shown in FIG. 4B as an example, but the disclosure is not limited thereto. In some embodiments, step S207 described with reference to FIGS. 5A to 5C may also be performed on the structure shown in FIG. 3C. In some embodiments, the heat dissipation layer 90 and the second circuit structure 70 may be formed by patterning a metal layer M1 after depositing the metal layer M1 having a thickness greater than the opening depth of the opening O1 in the Z-direction on the second side 10S2 of the electronic unit 10 and the bottom portion VMB of the conductive element VM to obtain the structure shown in FIG. 5A, but the disclosure is not limited thereto. In some embodiments, patterning the metal layer M1 includes forming an opening O3 exposing the bottom surface 30B of the encapsulation layer 30. The opening O3 may be between the electronic unit 10 and the via V1. In some embodiments, the opening O3 may partially overlap the electronic unit 10 in the Z direction, as shown in FIG. 5B, but the disclosure is not limited thereto.

In some embodiments, the method of manufacturing the electronic device of the present disclosure may further include a bonding layer formation step of disposing the bonding layer 20 on the second circuit structure 70 to electrically connect to other electronic devices, and a second protective layer formation step of disposing a second protective layer 60 surrounding the second circuit structure 70 on the second side 10S2 of the electronic unit 10 to reduce a risk of oxidation of the second circuit structure 70. In some embodiments, the second protective layer 60 may be disposed in the opening O3 and a gap may exist between the second protective layer 60 and the bonding layer 20 and the second circuit structure 70 in the X direction, as shown in FIG. 5C, but the disclosure is not limited thereto. In some embodiments, the second protective layer 60 may be in direct contact with the bonding layer 20 and the second circuit structure 70. In some embodiments, the bonding layer 20 and/or the second protective layer 60 may be omitted.

FIGS. 6A to 6E are schematic views of semi-finished products of an electronic device during manufacture of the electronic device according to an embodiment of the present disclosure. Specifically, FIGS. 6A to 6E are embodiments illustrating that step S201 in the method of manufacturing the electronic device of an embodiment of the present disclosure includes sequentially performing an electronic unit providing process, a via formation process, and a encapsulation layer formation process, wherein the encapsulation layer formation process including surface treatment step.

In the embodiment, the electronic unit providing process may include disposing a plurality of electronic units 10 on a carrier substrate C1 on which a release layer R1 and a seed layer A1 are disposed, wherein the seed layer A1 is disposed between the release layer R1 and the carrier substrate C1. In some embodiments, each electronic unit 10 may be disposed on the carrier substrate C1 such that the first side 10S1 faces the carrier substrate C1, but the disclosure is not limited thereto. The via formation process may include disposing a plurality of vias V1 on the carrier substrate C1 such that the top portions VMT of the conductive elements VM face the carrier substrate C1. In some embodiments, the via V1 may be disposed between two electronic units 10, but the disclosure is not limited thereto. The encapsulation layer formation process may include forming an encapsulation layer 30 on the carrier substrate C1, wherein the encapsulation layer 30 surrounds the electronic unit 10 and the via V1. The encapsulation layer 30 may be in direct or indirect contact with the second side 10S2 of the electronic unit 10 and with the bottom portion VMB and the side VMS of the via V1, as shown in FIG. 6A. In the embodiment, in the Z-direction, the electronic unit 10 may have a first height H1, the via V1 may have a second height H2, and the encapsulation layer 30 may have a thickness T1, wherein the thickness T1>the second height H2>the first height H1.

The structure as shown in FIG. 6A may be inverted onto a carrier substrate C2 on which a release layer R2 and a seed layer A2 are disposed before step S203, wherein the seed layer A2 is disposed between the release layer R2 and the carrier substrate C2. The release layer R1, the seed layer A1, and the carrier substrate C1 may be removed before step S203 to expose the input/output pads 101P and the first side 10S1 of the electronic unit 10, and the top portion VMT of the via V1. In some embodiments, the upper surface 30U of the encapsulation layer 30 and the first side 10S1 of the electronic unit 10 may be spaced apart by a step difference D1 in the Z-direction (see FIG. 6B) to reduce a risk of delamination of layers subsequently formed thereon. In some embodiments, the step difference D1 may be between 1 and 10 μm.

In step S203, the first circuit structure 50 including the first conductive layer 501 and the second conductive layer 503 may be provided on the input/output pads 101P and the first side 10S1 of the electronic unit 10 and on the top portion VMT of the via V1 to electrically connect the electronic unit 10 and the via V1. In some embodiments, the method of manufacturing the electronic device of the present disclosure may further include a first protective layer formation step of forming a first protective layer 40 on the first circuit structure 50 to reduce a risk of oxidation of the first circuit structure 50. The structure obtained after the first protective layer formation step is shown in FIG. 6B, but the disclosure is not limited thereto. In some embodiments, the first protective layer 40 may be omitted.

Before performing step S205, the structure obtained from step S203 may be inverted onto a carrier substrate C3 on which a release layer R3 and a seed layer A3 are disposed, wherein the seed layer A3 is disposed between the release layer R3 and the carrier substrate C3. The release layer R2, the seed layer A2, and the carrier substrate C2 may be removed to expose the bottom surface 30B of the encapsulation layer 30 before step S205. Step S205 may include an encapsulation layer removal step to remove a portion of the encapsulation layer 30, and an opening etching step to form an opening O1. In the embodiment, the encapsulation layer removal step may be performed until the bottom portion VMB of the conductive element VM is exposed, as shown in FIG. 6C, but the disclosure is not limited thereto. In some embodiments, the bottom portion VMB of the conductive element VM may be still covered by the encapsulation layer 30 after the encapsulation layer removal step. The encapsulation layer removal step may include a grinding process. The opening etching step is performed after the encapsulation layer removal step. In some embodiments, the opening etching step may include a first etch process to etch the entire encapsulation layer 30 and a second etch process to partially etch a portion of the encapsulation layer 30 on the back surface 101B of the chip 101. The first etching process may cause the bottom portion VMB of the conductive element VM to protrude from the bottom surface 30B of the encapsulation layer 30 to reduce a risk of delamination of the layer subsequently formed thereon. The second etching process may form the plurality of openings O1 exposing the back surface 101B of the chip 101. In some embodiments, the first etching process may be omitted. In some embodiments, after the first etching process, the encapsulation layer 30 may have a thickness T1 in the Z-direction (as shown in FIG. 6D). In some embodiments, the opening O1 formed by the second etching process may have an opening width W2 (as shown in FIG. 6D) in the first direction (i.e., the X direction) and an opening depth in the normal direction of the electronic device (i.e., the Z direction). In some embodiments, the first etching process may include a plasma etching process, a laser etching process, a chemical etching process, another suitable etching process, or a combination thereof, but the disclosure is not limited thereto. In some embodiments, the second etching process may include a plasma etching process, a laser etching process, another suitable etching process, or a combination thereof, but the disclosure is not limited thereto.

The heat dissipation layer 90 and the second circuit structure 70 are formed on the second side 10S2 of the electronic unit 10 and the via V1 in step S207. The heat dissipation layer 90 is between the second circuit structure 70 and the second side 10S2 of the electronic unit 10 and the via V1 electrically connects the second circuit structure 70 and the first circuit structure 50. In some embodiments, the method of manufacturing the electronic device of the present disclosure may further include a bonding layer formation step of disposing a bonding layer 20 on the second circuit structure 70 to electrically connect with other electronic devices, and a second protective layer formation step of disposing a second protective layer 60 surrounding the second circuit structure 70 on the second side 10S2 of the electronic unit 10 to reduce a risk of oxidation of the second circuit structure 70. The structure obtained after the bonding layer formation step and the second protective layer formation step is shown in FIG. 6D, but the disclosure is not limited thereto. In some embodiments, the bonding layer 20 and/or the second protective layer 60 may be omitted.

In some embodiments, the method of manufacturing the electronic device of the present disclosure may further include a cutting process. The cutting process may separate the plurality of electronic units 10 to form an electronic device including one electronic unit 10 as shown in FIG. 6E.

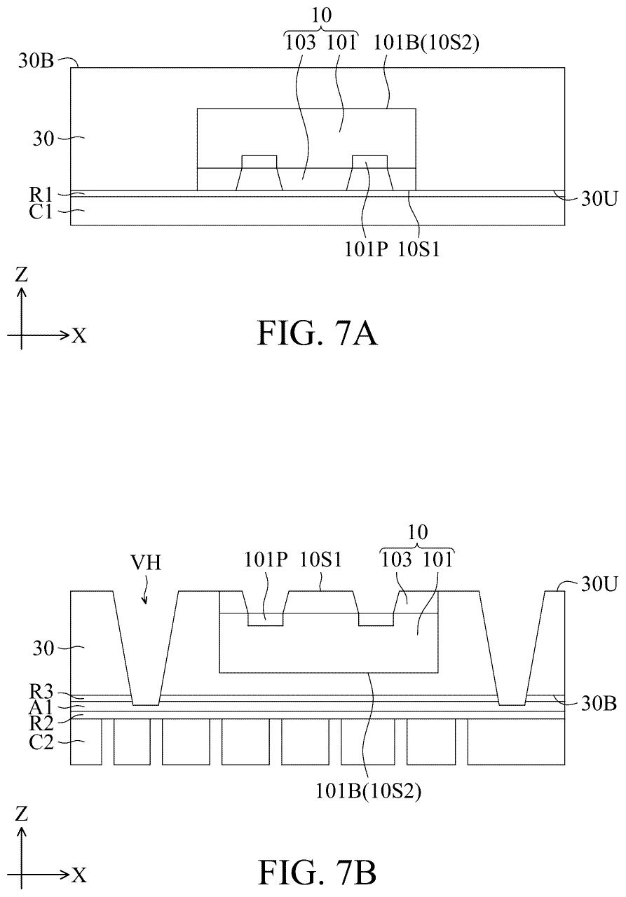

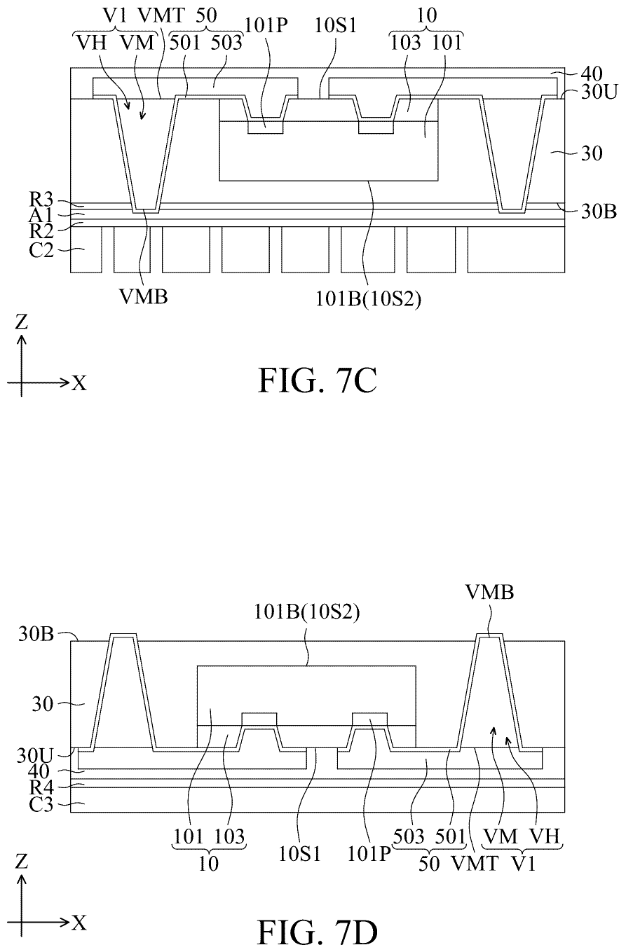

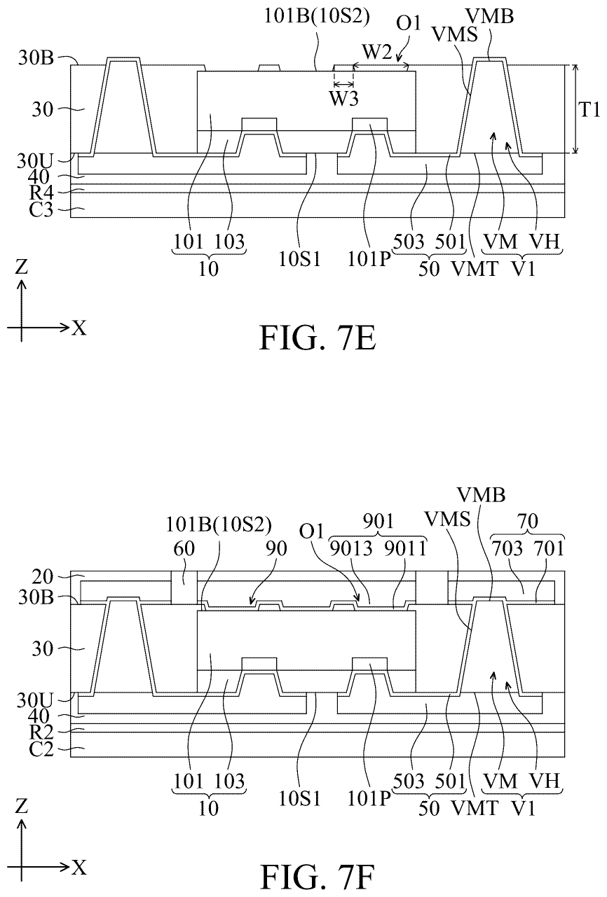

FIGS. 7A to 7F are schematic views of semi-finished products of an electronic device during the manufacture of the electronic device according to an embodiment of the present disclosure. The method of manufacturing the electronic device of the disclosure is further described below in conjunction with FIG. 2 and FIGS. 7A to 7F.

In the embodiment, step S201 of providing the electronic unit, the via, and the encapsulation layer may include an electronic unit providing process of providing the electronic unit 10 on the carrier substrate, a encapsulation layer formation process of forming the encapsulation layer 30, and a via formation process of forming the via V1. For example, in some embodiments, the electronic unit providing process may include disposing the electronic unit 10 having a first side 10S1 and a second side 10S2 opposite the first side 10S1 on the carrier substrate C1 having a release layer R1. In some embodiments, the electronic unit 10 may be disposed on the carrier substrate C1 such that the first side 10S1 faces the carrier substrate, but the disclosure is not limited thereto. The encapsulation layer formation process may include forming the encapsulation layer 30 on the carrier substrate C1. The encapsulation layer 30 surrounds the electronic unit 10 and is in direct or indirect contact with the second side 10S2 of the electronic unit 10 and the side of the electronic unit 10, as shown in FIG. 7A. In some of the embodiments, performing surface treatment to make the surface of the encapsulation layer 30 a rough surface, but not limited to. Before performing the via formation process, the structure shown in FIG. 7A may be inverted onto a porous carrier substrate C2, and the release layer R1 and the carrier substrate C1 may be removed to expose the first side 10S1 of the electronic unit 10 and the upper surface 30U of the encapsulation layer 30. In the embodiment, the porous carrier substrate C2 and the encapsulation layer 30 may be further interspersed with a release layer R2, a seed layer A1, and a release layer R3. The seed layer A1 is disposed between the release layer R2 and the release layer R3, and the release layer R2 is disposed between the seed layer A1 and the porous carrier substrate C2. The via formation process is performed at the upper surface 30U of the encapsulation layer 30. In one embodiment, the via formation process may include forming a through-hole opening VH (shown in FIG. 7B) extending from the upper surface 30U of the encapsulation layer 30 into the seed layer A1 and forming a conductive element VM in the through-hole opening VH. Specifically, in some embodiments, the forming of the through-hole opening VH may include first forming an opening exposing the release layer R3 by a laser perforation process, a mechanical perforation process, and/or a photolithography process, and removing the release layer R3 and a portion of the seed layer A1 by a chemical etching process. In some embodiments, step S203 of forming the first circuit structure 50 including the first conductive layer 501 and the second conductive layer 503 may be performed simultaneously with the step of forming the conductive element VM in the through-hole opening VH. That is, the first circuit structure 50 and the conductive element VM may be formed by the same process to simplify the manufacture process of the electronic device of the present disclosure. In this embodiment, the bottom portion VMB of the conductive element VM formed in the through-hole opening VH protrudes from another surface of the encapsulation layer 30, as shown in FIG. 7C, but the disclosure is not limited thereto.

In some embodiments, the method of manufacturing the electronic device of the present disclosure may further include a first protective layer formation step of forming a first protective layer 40 on the first circuit structure 50 to reduce a risk of oxidation of the first circuit structure 50. In some of the embodiments, before providing the first protective layer 40, performing surface treatment to make a surface (ex: a surface of the first conductive layer 501) of first circuit structure 50 a rough surface to reduce the risk of the delamination between different layers, for example, first circuit structure 50 and the first protective layer 40, and a roughness of the first circuit structure 50 is different from a roughness of the but not limited to. The structure obtained after the first protective layer formation step is shown in FIG. 7C, but the disclosure is not limited thereto. In some embodiments, the first protective layer 40 may be omitted. In some of the embodiment, step S203 further comprises performing surface treatment to make a surface of first protective layer 40 a rough surface if it needs to provide another conductive layer on it, wherein a roughness od the first protective layer 40 is different from the roughness of the conductive layer.

Before performing step S205, the structure obtained from step S203 may be inverted onto a carrier substrate C3 on which a release layer R4 is disposed. The release layer R2, the seed layer A1, the release layer R3, and the porous carrier substrate C2 may be removed to expose the bottom surface 30B of the encapsulation layer 30. The encapsulation layer removal step in step S205 may then be performed until the bottom portion VMB of the conductive element VM is exposed. The encapsulation layer removal step may include a grinding process. The opening etching step in step S205 may be performed after the encapsulation layer removal step. In some embodiments, the open etch step may include a first etching process to etch the entire encapsulation layer 30 and a second etching process to partially etch a portion of the encapsulation layer 30 on the back surface 101B of the chip 101. The structure obtained after the first etching process is shown in FIG. 7D, and the structure obtained after the second etching process is shown in FIG. 7E. In some embodiments, after the first etching process, the encapsulation layer 30 may have a thickness T1 in the Z-direction. The first etching process may cause the bottom portion VMB of the conductive element VM to protrude from the bottom surface 30B of the encapsulation layer 30 to reduce a risk of delamination of layers subsequently formed thereon. The second etching process may form a plurality of openings O1 exposing the back surface 101B of the chip 101. In some embodiments, the openings O1 have an opening width W2 in a first direction (i.e., the X direction) and an opening depth in the normal direction of the electronic device (i.e., the Z direction). In some embodiments, the first etching process may include a plasma etching process, a laser etching process, a chemical etching process, other suitable etching process, or a combination thereof, but the disclosure is not limited thereto. In some embodiments, the second etching process may include a plasma etching process, a laser etching process, another suitable etching process, or a combination thereof, but the disclosure is not limited thereto.

The heat dissipation layer 90 and the second circuit structure 70 are formed on the second side 10S2 of the electronic unit 10 and the via V1 in step S207. The heat dissipation layer 90 is between the second circuit structure 70 and the second side 10S2 of the electronic unit 10 and the via V1 electrically connects the second circuit structure 70 and the first circuit structure 50. The obtained structure is shown in FIG. 7F. Step S207 described in this embodiment is substantially the same as step S207 described above, and therefore will not be repeated herein.

In some embodiments, the method of manufacturing the electronic device of the present disclosure may further include a bonding layer formation step of disposing a bonding layer 20 on the second circuit structure 70 to electrically connect with other electronic devices, and a second protective layer formation step of disposing a second protective layer 60 surrounding the second circuit structure 70 on the second side 10S2 of the electronic unit 10 to reduce a risk of oxidation of the second circuit structure 70. The structure obtained after the bonding layer formation step and the second protective layer formation step is shown in FIG. 7F, but the disclosure is not limited thereto. In some embodiments, the bonding layer 20 and/or the second protective layer 60 may be omitted.

The electronic device manufactured according to the above method of manufacturing the electronic device disclosed herein may have a smaller size. When the electronic device of the present disclosure is electrically connected to other electronic devices by the bonding layer, a shorter path between the electronic device and the other electronic devices improves the reliability and electrical properties of the electronic device. In addition, the manufacturing method of the electronic devices of the disclosure can improve the quality of the electronic devices by eliminating the problem of metal smearing caused by a grinding process.

Although embodiments of the present disclosure and the advantages thereof have been disclosed as above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. An electronic device, comprising:
an electronic unit having a first side and a second side opposite the first side;
an encapsulation layer surrounding the electronic unit and having a plurality of openings exposing the second side of the electronic unit;
a first circuit structure disposed on the first side of the electronic unit and electrically connected to the electronic unit;
a second circuit structure disposed on the second side of the electronic unit;
a via penetrating through the encapsulation layer and electrically connected to the first circuit structure and the second circuit structure; and
a heat dissipation layer disposed on the second side of the electronic unit,
wherein the heat dissipation layer contacts the electronic unit through the plurality of openings.

2. The electronic device as claimed in claim 1, wherein the electronic unit comprises a chip and a protective layer, and the heat dissipation layer contacts a back surface of the chip through the plurality of openings.

3. The electronic device as claimed in claim 2, wherein a ratio of a sum of contact widths of the heat dissipation layer contacting the back surface of the chip/a back surface width of the backs surface of the chip is between 0.2 and 0.7.

4. The electronic device as claimed in claim 2, wherein the encapsulation layer has a thickness T1, the encapsulation layer between the chip and the second circuit structure has a thickness T2, and the thickness T2/the thickness T1 is range from 0.01-0.5.

5. The electronic device as claimed in claim 1, wherein the second circuit structure is electrically connected to the heat dissipation layer.

6. The electronic device as claimed in claim 1, wherein a thermal conductivity of the heat dissipation layer is greater than or equal to 10 W/mK and less than or equal to 505 W/mK.

7. The electronic device as claimed in claim 1, wherein the via has a bottom portion, a top portion, and a side connecting the bottom portion and the top portion, wherein the bottom portion of the via connects the second circuit structure and the bottom portion protrudes from the bottom surface of the encapsulation layer.

8. The electronic device as claimed in claim 1, wherein the via has a bottom portion, a top portion, and a side connecting the bottom portion and the top portion, wherein the bottom portion of the via connects the second circuit structure and the side of the via comprises a stepped edge.

9. The electronic device as claimed in claim 1, further comprising a bonding layer disposed on the second circuit structure.

10. The electronic device as claimed in claim 1, further comprising a second protective layer on the encapsulation layer, wherein the second protective layer surrounds the second circuit structure.

11. A method of manufacturing an electronic device, comprising:
providing an electronic unit, a via, and an encapsulation layer, wherein the encapsulation layer surrounds the electronic unit and the via and exposes a first side of the electronic unit and a top portion of a conductive element of the via;
providing a first circuit structure on the first side of the electronic unit and the via;
forming a plurality of first openings to expose a portion of a second side of the electronic unit; and
forming a heat dissipation layer on the second side of the electronic unit and forming a second circuit structure on the via,
wherein the second circuit structure electrically connects the first circuit structure through the via and the heat dissipation layer is between the second circuit structure and the second side of the electronic unit.

12. The method of manufacturing an electronic device as claimed in claim 11, wherein the electronic unit comprises a chip and a protective layer, and the heat dissipation layer contacts a back surface of the chip through the plurality of first openings.

13. The method of manufacturing an electronic device as claimed in claim 12, wherein a ratio of a sum of contact widths of the heat dissipation layer contacting the back surface of the chip/a back surface width of the back surface of the chip is between 0.2 and 0.7.

14. The method of manufacturing an electronic device as claimed in claim 12, wherein the encapsulation layer has a thickness T1, the encapsulation layer between the chip and the second circuit structure has a thickness T2, and the thickness T2/the thickness T1 is range from 0.01-0.5.

15. The method of manufacturing an electronic device as claimed in claim 11, wherein the step of forming the plurality of first openings comprises an encapsulation layer removal step to remove a portion of the encapsulation layer and an opening etching step to form the plurality of first openings, wherein the encapsulation layer removal step is performed until a conductive element of the via is exposed.

16. The method of manufacturing an electronic device as claimed in claim 15, wherein the opening etching step comprises etching the encapsulation layer surrounding the conductive element to cause a bottom portion of the conductive element to protrude from the encapsulation layer.

17. The method of manufacturing an electronic device as claimed in claim 11, wherein the step of forming the plurality of first openings comprises an encapsulation layer removal step to remove a portion of the encapsulation layer and an opening etching step to form the plurality of first openings, wherein a bottom portion of the conductive element is still covered by the encapsulation layer after the encapsulation layer removal step.

18. The method of manufacturing an electronic device as claimed in claim 17, wherein the opening etching step comprises partially etching the encapsulation layer on the bottom portion of the conductive element to form a second opening exposing the bottom portion of the conductive element.

19. The method of manufacturing an electronic device as claimed in claim 18, wherein a width of the second opening is greater than a width of the bottom portion of the conductive element.

20. The method of manufacturing an electronic device as claimed in claim 11, wherein in the step of providing an electronic unit, a via, and an encapsulation layer, the electronic unit has a first height H1, the via has a second height H2, the encapsulation layer has a thickness T1, and the thickness T1>the second height H2>the first height H1.
